(19) United States
(12) Patent Application Publication
(10) Pub. No.: US 2026/0037703 A1
(43) Pub. Date: Feb. 5, 2026

(54) Computer-Implemented Method and System for Generating Simulation Models for a Digital Twin of a Process of a Production Installation for a Product

(71) Applicant: Siemens Aktiengesellschaft, Muenchen (DE)

(72) Inventor: Bernd-Markus PFEIFFER, Uttenreuth (DE)

(21) Appl. No.: 19/099,110

(22) PCT Filed: Jul. 18, 2023
(86) PCT No.: PCT/EP2023/069880

§ 371 Date: Jan. 28, 2025

(30) Foreign Application Priority Data
Jul. 29, 2022 (EP) 22187765.7

(51) Int. Cl. G06F 30/28

(52) U.S. Cl. CPC G06F 30/28

(57) ABSTRACT

A method for generating, for a digital twin of a process of a production installation, a stationary flow-driven simulation model of a process and, based on this simulation model, a stationary pressure-driven simulation model of the process, wherein the model is used to generate a dynamic pressure-driven simulation model of the process, where each simulation model determines measurable state variables and characteristic values for product quality of the production installation based on material flows of feedstocks and operating media supplied to the production installation, where model data of each simulation model is generated and stored in memory, such that they readable by simulation software and used to execute simulation models, where the model is continually developed further and matched to respective applications without losing information from earlier phases or having to manually reenter information such that development of a digital process twin can be amortized over multiple incidents of use.

### CROSS-REFERENCE TO RELATED APPLICATIONS

This is a U.S. national stage of application No. PCT/EP2023/069880 filed 18 Jul. 2023. Priority is claimed on European Application No. 22187765.7 filed 29 Jul. 2022, the content of which is incorporated herein by reference in its entirety.

### BACKGROUND OF THE INVENTION

### 1. Field of the Invention

The invention relates to a computer-implemented method and a system for generating simulation models for a digital twin of an industrial process in a production plant for a product.

### 2. Description of the Related Art

Process-based production plants are used for the production and conversion of products (or substances) with no precisely defined shape. Such installations are used primarily in the process industry, for example, in the paper, chemical, pharmaceutical, metal, oil, and gas industries. They are typically highly complex facilities with numerous operating modes, a large spatial extent, and involve the interaction of a large number of components. For operator control and monitoring, and open/closed loop control of the processes, these installations generally include a process control system. Examples of such systems are the PCS 7 and PCS neo process control systems of the applicant.

So-called “digital twins” of the process are also being increasingly used. Such a digital twin usually includes planning data from the design and engineering phase of the process as well as data from the operational phase, but also behavioral descriptions in the form of simulation models. A “digital process twin” of this kind can be used for various applications throughout the lifecycle of a production plant.

The article “Evolution eines Digital Twin am Beispiel einer Ethylen-Anlage—Konzept und Umsetzung” (Evolution of a digital twin using the example of an ethylene plant—concept and realization) by Labisch D., Leingang C., Lorenz O., Oppelt M., Pfeiffer B.-M., Pohmer F. in “atp magazin” 06-07/2019, pages 70 to 85, describes a concept for the development and consistent use of a digital twin over the entire lifecycle of a process plant. The approach pursued involves integrating individual models and software tools into a consistent, semantically linked system, spanning various hierarchical levels of a plant and the different phases of the lifecycle of the plant. The use of simulation in relation to the phases of the plant lifecycle is divided into four groups: planning simulation, virtual commissioning simulation, training simulation, and operational support simulation (soft sensors, model predictive control). The article envisions a future in which models, once developed, are reused and continuously refined throughout the lifecycle.

The concept is explained using the example of a steam cracker. The start of the lifecycle of the plant is the plant design phase. Here, based on existing plant knowledge and current findings from publications, an initial “digital process twin” is created using simulation software. This digital twin is used for designing the plant and its components (conceptual design). For a cracker, for example, this includes defining the chemical reaction or determining the optimal reactor sizes and wall thicknesses. The sizing of pumps, heat exchangers, and buffer tanks is also performed using steady-state simulation models. As the engineering progresses, the digital process twin generated using the simulation software is transferred in the form of a process flow diagram into the plant planning tool, forming the basis for a “digital plant twin”. This twin is progressively expanded to include other plant-relevant aspects, such as sensors, actuators, and controller structures, resulting in a piping and instrumentation diagram (P&ID). The analysis and validation of controller concepts occur in parallel using a dynamic simulation model, which means that the two digital twins are continuously synchronized. Changes in the digital plant twin directly affect the digital process twin. Design errors can be identified and corrected early using dynamic model simulations.

A “digital instrumentation twin” is used to validate a created automation program as part of virtual commissioning and to identify malfunctions before actual commissioning. For a plant operator training system, the digital process twin is linked to a simulation model of the digital instrumentation twin. A detailed process simulation created as early as the conceptual design phase in process simulation software can therefore be used throughout the entire lifecycle.

Table 1 of the article presents various components of a digital twin along with their intended purposes. For example, a dynamic, simplified linearized model of a unit (reactor, cracker) can be used during the lifecycle for the following tasks: automation concept planning (proportional-integral-derivative (PID) controller design), virtual commissioning, actual commissioning (use or updating of the model for PID tuning), operational phase optimization (MPC), and control loop monitoring (CPM). For these purposes, the model is transferred into various software tools or updated there.

A precise, rigorous dynamic model is implemented in the simulation tool gPROMS from Siemens Process Systems Engineering Ltd. and can be used for planning operating procedures (recipes) during detailed engineering, automation concept planning, operator training in the operational phase, and model-based soft sensors.

With a unit as an example, a rigorous steady-state model is first developed as part of basic engineering. Once dynamics-related parameters, such as tank volumes, heat capacities and/or pump power are known, a preliminary dynamic model can be derived therefrom that can already simulate a water run. This model is then refined into a precise dynamic model, including chemical reactions and their reaction kinetics. Simplified dynamic models for control engineering purposes can be extracted from the rigorous dynamic model.

Regarding the prior art, reference is also made to the article by Busse, C., Bozek, E., Pfeiffer, B.-M., Leingang, Ch., Roth, M., Krauβ, M., Schulz, Ch., Oppelt, M.: “Integration digitaler Technologien für das Engineering, den Betrieb und die Instandhaltung einer verfahrenstechnischen Anlage” (Integration of Digital Technologies for the Engineering, Operation, and Maintenance of a Process Plant) in Chemie Ingenieur Technik 92(9):1250-1250 September 2020.

Reference is further made to Pfeiffer, B.-M., Oppelt, M., Leingang, Ch., Pantelides, C., Pereira, F.: “Nonlinear Model Predictive Control Based on Existing Mechanistic Models of Polymerization Reactors” in IFAC World Congress 2020, Berlin (virtual), July 2020.

### SUMMARY OF THE INVENTION

Proceeding on the foregoing basis, it is an object of the present invention to provide a computer-implemented method and a system that facilitate an efficient generation of simulation models for a digital twin of a process within a production plant throughout its lifecycle.

This and other objects and advantages are achieved in accordance with the invention by a computer-implemented method, a system, a computer program comprising commands that, when executed by a processor of a computer, cause the computer to carry out the inventive method, and by a computer-readable storage medium containing commands that, when executed by a processor of a computer, cause the computer to carry out the inventive method.

The computer-implemented method in accordance with the invention for generating simulation models for a digital twin of a process of a process-based production plant for a product comprises:
a) receiving process flow planning data (for example, from a process flow diagram) of the process of the production plant,
b) generating a steady-state flow-driven simulation model of the process from the process flow planning data,
c) generating a steady-state pressure-driven simulation model of the process from the steady-state flow-driven simulation model,
d) receiving piping and instrumentation planning data (for example, from a P&I diagram) of the production plant,
e) generating a dynamic pressure-driven simulation model of the process from the steady-state pressure-driven simulation model and the piping and instrumentation planning data, where the dynamic pressure-driven simulation model comprises sensors and actuators of control loops of the plant.

For each of the simulation models, measurable state variables of the production plant, preferably also product quality metrics, are determined based on material flows of feedstocks (for example, hydrocarbons) and operating media (for example, heating steam, cooling water) supplied to the production plant.

In addition, model data from each of the simulation models (i.e., data that describes or defines the simulation models) is generated (for example, regarding selection, content, structure) and stored in a data memory such that the model data can be read by simulation software and the simulation models can be executed based on the read model data.

In accordance with the invention, a first simulation model of the process, in this case the steady-state flow-driven simulation model of the process, is thus converted into other simulation models of the process by model transformation. The model transformation enables the first simulation model of the process to be used consistently in a digital twin of the process (“digital process twin”) for various use cases in the lifecycle of a plant. It has been found that the model transformation (see steps b), c), e)) covers the key use cases for a digital twin of a production process.

In accordance with the invention, each of the simulation models determines measurable state variables (for example, temperatures, pressures, fill levels, and/or pH values) of the production plant, and preferably also product quality metrics, based on the material flows of feedstocks and operating media supplied to the production plant. Here, the underlying insight is that these variables can also cover the most important use cases for a digital twin in a production process: the measurable state variables describe the state of the production plant or rather the production process, and the product quality is the key criterion for the success of the process. Most procedures in a production plant are “nonlinear”. Consequently, the simulation models are preferably nonlinear models. For example, the flow through a valve often varies nonlinearly with respect to the valve position. The pressure or head of a centrifugal pump varies as the square of the pump speed. The rate of a chemical reaction always varies nonlinearly with respect to the temperature.

A “flow-driven” simulation is to be understood as meaning a simulation in which the flow rates are specified starting from the feedstock supply, and a pressure distribution in the flow network and flow rates are calculated independently of each other.

A “pressure-driven” simulation is understood as meaning a simulation where a feedstock is taken from a source (for example, a supply line) with defined pressure, and a flow rate in each component of the flow network is determined from pressure difference and flow resistance.

In accordance with an advantageous embodiment of the inventive method, the dynamic pressure-driven simulation model generated in step e) already includes actuators of secondary control loops, in particular fluid mechanics models of actuators of secondary control loops, of the control loops, or it is extended to include these in a further step f). This can increase still further the number of applications of the digital process twin.

In accordance with another advantageous embodiment of the inventive method, the dynamic pressure-driven simulation model generated in step e) or f) already includes PID controllers of the control loops, or it is extended to include these in a further step g). This can also increase still further the number of applications of the digital process twin.

The simulation model generated in step b) and/or c) can then be used advantageously for process engineering design of the production plant, and the production plant can be physically implemented in accordance with this design.

The simulation model created in step e), f) or g) can be used for the development and validation of control concepts, and the control of the production plant can then be physically implemented in accordance with this design.

The simulation model generated in step e), f) or g) is preferably used for virtual commissioning of the plant and is linked to the plant's control software for this purpose in order to test it for errors. Information about an error or absence of errors can then be output on an output unit (for example, a display). In the event of an error, the control software can then be corrected.

The simulation model generated in step e), f) or g) can be used to train plant operators and can be linked to plant operator control and monitoring software for this purpose.

In accordance with another advantageous embodiment, the simulation model generated in step e), f) or g) is used for a model-based soft sensor of the plant. A soft sensor receives measured variables from the plant as input and uses them to determine variables of the plant that cannot be measured (or are difficult to measure), particularly metrics relating to product quality in a production process.

The simulation model generated in step e), f) or g) can also advantageously be used for model-based predictive control of the plant.

In accordance with another advantageous embodiment, the simulation model generated in step e), f) or g) is used for an assistance system for the plant operator and is linked to the plant's control software for this purpose.

An inventive system for generating simulation models for a digital twin of a process in a process-based production plant comprises
an interface that is configured to
   a) receive process flow planning data and piping and instrumentation planning data of the production plant and
   b) output model data of each of the simulation models for storage in a data memory,
a memory containing commands,
a processor linked to the memory and configured, when executing the commands, to perform steps a) to e), preferably also the further steps f) and/or g), of the above-described method, where each of the simulation models determines measurable state variables of the production plant, preferably also product quality metrics based on material flows of raw materials and operating media supplied to the production plant, and where the model data is generated such that the simulation models can be executed by simulation software on the basis of the model data.

A computer program in accordance with the invention comprises commands which, when the program is executed by a computer, cause the computer to perform the above-described method.

A computer-readable storage medium in accordance with the invention comprises commands which, when executed by a computer, cause the computer to performed the above-described method.

The advantages and advantageous embodiments cited for the inventive method also apply in a corresponding manner to the inventive system.

Other objects and features of the present invention will become apparent from the following detailed description considered in conjunction with the accompanying drawings. It is to be understood, however, that the drawings are designed solely for purposes of illustration and not as a definition of the limits of the invention, for which reference should be made to the appended claims. It should be further understood that the drawings are not necessarily drawn to scale and that, unless otherwise indicated, they are merely intended to conceptually illustrate the structures and procedures described herein.

### BRIEF DESCRIPTION OF THE DRAWINGS

The invention and further advantageous embodiments of the invention according to features of the dependent claims will now be explained in more detail with reference to exemplary embodiments shown in the figures. Corresponding parts are provided with the same reference characters in each case, in which:

FIG. 1 shows an exemplary schematic layout of a process-based production plant for a product;

FIG. 2 shows a steam cracker as an example of a process-based production plant;

FIG. 3 shows a flowchart for the inventive method;

FIGS. 4 and 5 schematically illustrate a digital process twin for process engineering design of a plant;

FIG. 6 schematically illustrates a digital process twin for the development and validation of control concepts;

FIG. 7 schematically illustrates a digital process twin for the virtual commissioning of the plant;

FIG. 8 schematically illustrates a digital process twin for the training of operating personnel for the plant;

FIG. 9 schematically illustrates a digital process twin for a model-based soft sensor of the plant;

FIG. 11 schematically illustrates a digital process twin for model-based predictive control of the plant;

FIG. 12 schematically illustrates a system in accordance with the invention.

### DETAILED DESCRIPTION OF THE EXEMPLARY EMBODIMENTS

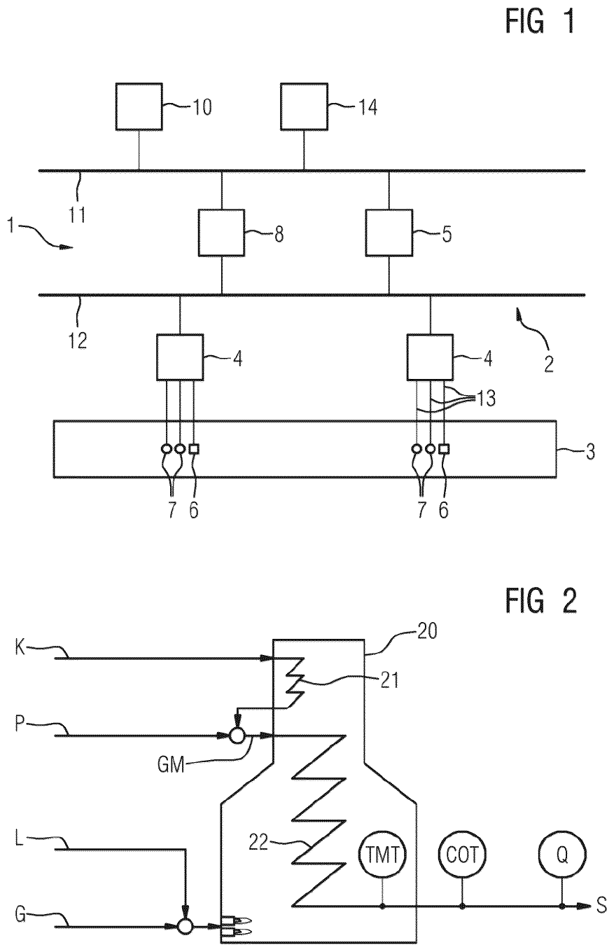

FIG. 1 shows a simplified and exemplary representation of a process-based production plant 1 for a product, comprising an automation system 2 for open and/or closed-loop control of a production process 3. The term “production process” here refers not only to a manufacturing process, but also to a treatment, processing or conversion process (for example, also an energy generation process).

Such plants 1 are used in a wide variety of industrial sectors, such as in the process industry (for, example paper, chemicals, pharmaceuticals, metal, oil and gas) and in power generation. The automation system 2 typically comprises a plurality of industrial controllers 4, an automation server 5 and an engineering server 8.

Each of the controllers 4 controls the operation of a specific part of the process 3 as a function of its operating states. For this purpose, the process 3 includes actuators 6 that can be controlled by the controllers 4. These can be individual actuators (for example, a motor, pump, valve, switch), groups of such actuators or entire sections of a plant. The process also includes sensors 7 that provide the controllers 4 with measured values of process variables (for example, temperatures, pressures, fill levels, flow rates).

A communication network of plant 1 comprises, at a higher level, a plant network 11 via which the servers 5, 8 communicate with a human-machine interface (HMI) 10, and a control network 12 via which the controllers 4 communicate with each other and with the servers 5, 8. The connection of the controllers 4 with the actuators 6 and sensors 7 can be established via discrete signal lines 13 or via a field bus. The human-machine interface (HMI) 10 is typically structured as an operator control and monitoring station and is located in a control room of the plant 1.

The automation server 5 can typically be an “operator system server” or “application server” in which one or more plant-specific application programs are stored and executed during operation of the plant 1. These are used, for example, to configure the controllers 4 in the plant 1, to record and execute operator activities at the human-machine interface (HMI) 10 (for example, to set or change setpoints for process variables) or to generate messages for plant personnel and display them on the human-machine interface (HMI) 10.

The automation system 2, excluding the field devices (i.e., without the actuators 6 and sensors 7), is often also referred to as a “process control system”.

A large number of the components described above are used in large industrial production plants. Sometimes multiple production processes 3 can also be performed simultaneously. The sensors 7 therefore provide a plethora of measurement data for process variables of the process 3. This measurement data is stored on a process data archive server 14, along with messages from the automation server 5 and additional information (for example, batch data, status information of intelligent field devices).

As shown in FIG. 2, the process 3 can typically be a steam cracking process. Steam cracking is a petrochemical process in which long-chain hydrocarbons (naphtha, but also ethane, propane and butane) are thermally cracked in the presence of steam to produce short-chain hydrocarbons such as ethylene, propylene and butene.

Steam cracking is implemented in a steam cracker 20, shown schematically in FIG. 2 with the main material flows. It is used to produce intermediate products that are mainly processed into plastics (for example, polyethylene), paints, solvents or pesticides. The steam cracker 20 is a tubular reactor that is supplied with hydrocarbons K as feedstock and process steam P, air L and fuel gas G as operating media. The hydrocarbons K and the mixture GM of hydrocarbon K and process steam P are heated via tube bundles 21, 22. During this process, the long-chain molecules are thermally cracked within fractions of a second. FIG. 2 shows a simplified representation of a single coil. COT (coil outlet temperature) and TMT (tube metal temperature) describe temperatures and thus state variables of the steam cracker 20. The output product from the steam cracker 20 is cracked gas S, the quality Q of which can be measured using a measuring device.

A plurality of such steam crackers 20 can be disposed, for example, at the beginning of the material flow of an ethylene plant. Several large steam crackers 20 are then operated in parallel. In a downstream, multi-stage separation process involving distillation columns, steam separators, coolers and similar apparatus, various usable products are then separated.

A “digital twin” of the process 3 of the production plant 1 from FIG. 1, or, for example, of the steam cracking process in the steam cracker 20 from FIG. 2, can be advantageously employed in various phases of the plant lifecycle. The “digital twin” of the process will hereinafter also be referred to as a “digital process twin”. It generally includes planning data from the design and engineering phase as well as plant data from the operational phase, along with behavioral descriptions in the form of models, particularly mathematical models. The digital twin evolves throughout the plant lifecycle and integrates existing data and knowledge bases at each stage.

With successive model transformation, the invention now paves the way for the consistent use of a digital process twin for various use cases in the lifecycle of a plant. In addition to the behavioral description of the actual process, the basic automation of the plant, implemented through numerous PID controllers, is also taken into account in the various model transformations and requires particular attention: the dynamics of the controllers, their additional logical functions and their role in the context of the use cases mentioned. In the following, several use cases will be considered in turn and the necessary model transformations will be described. It is taken into consideration that different use cases also place different demands on the digital process twin. The outlay required to create a digital process twin can now advantageously be amortized over multiple use cases.

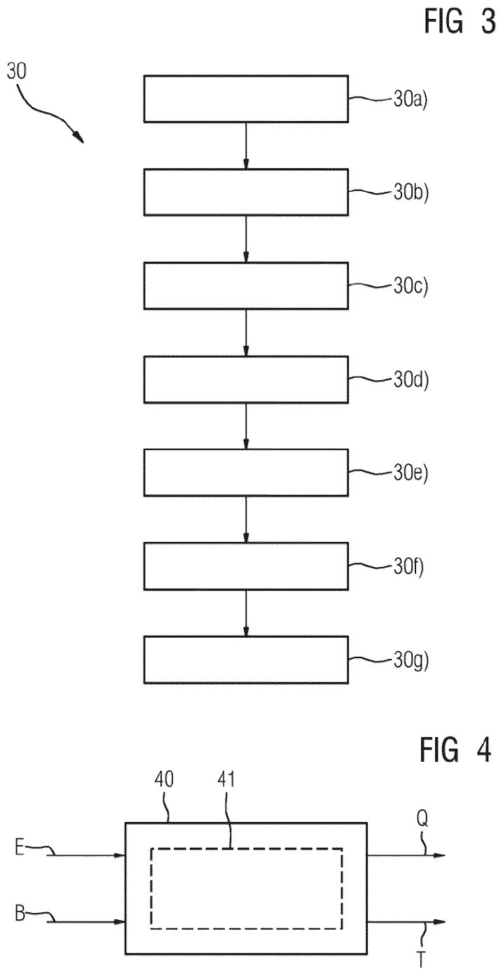

As shown in FIG. 3, an inventive computer-implemented method 30 for generating simulation models for digital twins of a process in an industrial production plant for a product comprises the following steps:
in a first step 30 a): receiving process flow planning data (for example, relating to the process flow diagram) of the production plant process,
in a second step 30 b): generating a steady-state flow-driven simulation model of the process from the process flow planning data,
in a third step 30 c): generating a steady-state pressure-driven simulation model of the process from the steady-state flow-driven simulation model,
in a fourth step 30 d): receiving piping and instrumentation planning data (for example, from a P&I diagram) of the production plant,
in a fifth step 30 e): generating a dynamic pressure-driven simulation model of the process from the steady-state pressure-driven simulation model and the piping and instrumentation planning data, where the dynamic pressure-driven simulation model includes sensors and actuators of control loops in the production plant,
in a sixth step 30 f): expanding the dynamic pressure-driven simulation model of the process to include actuators of secondary control loops, specifically fluid mechanics models of actuators of secondary control loops, in the production plant,
in a seventh step 30 g): expanding the dynamic pressure-driven simulation model from step 30 f) to include PID controllers of the control loops of the production plant.

Each of the simulation models determines product quality metrics and measurable state variables of the production plant based on the material flows of feedstocks and operating media supplied to the production plant.

Model data from each of the simulation models (i.e., data describing or defining the simulation models) is generated (for example, with regard to selection, content, structure) and stored in a data memory such that the model data can be read by simulation software, allowing the simulation models to be executed based on the read model data.

As shown in FIGS. 3 and 4, the starting point in step 30 a) involves receiving process flow planning data (for example, from a process flow diagram) of the production plant process, and then, in step 30 b, generating a steady-state flow-driven simulation model 41 for a planned operating point of the process. For example, based on the PFD (process flow diagram), the flow network is constructed in a simulation tool, where possible by connecting existing component models (e.g., stirred tank reactors, distillation columns, heat exchangers, and/or tanks) from model libraries with material flow connections (pipelines without flow resistance), branches and mixers. The flow network is first modeled as a steady-state flow-driven simulation, i.e., the flow rates are specified starting from the raw material supply, and the pressure distribution in the flow network and the flow rates are calculated independently of each other.

These simulations are used to design and select plant components, such as reactors, columns, pumps, heat exchangers, etc. In this phase, for example, a feed line to a steam cracker is merely represented in the simulation model as a material flow source with defined material concentrations and nominal flow rate.

The digital process twin 40 includes the simulation model 41 and has, as input variables for the simulation model 41, values for the material flows of feedstocks E and operating media B supplied to the process or the production plant. Output variables of the simulation model 41 or rather of the digital process twin 40 are values of metrics for product quality Q (for example, purity, homogeneity) and values for measurable state variables such as temperature T. Here, T stands for additional state variables such as flow rate, pressure, and/or fill level of the production plant as a function of the input variables.

The simulation model 41 is typically based on a mathematical model of process behavior, the result of rigorous modeling proceeding from physical, chemical and thermodynamic laws. The simulation model 41 is preferably a nonlinear model.

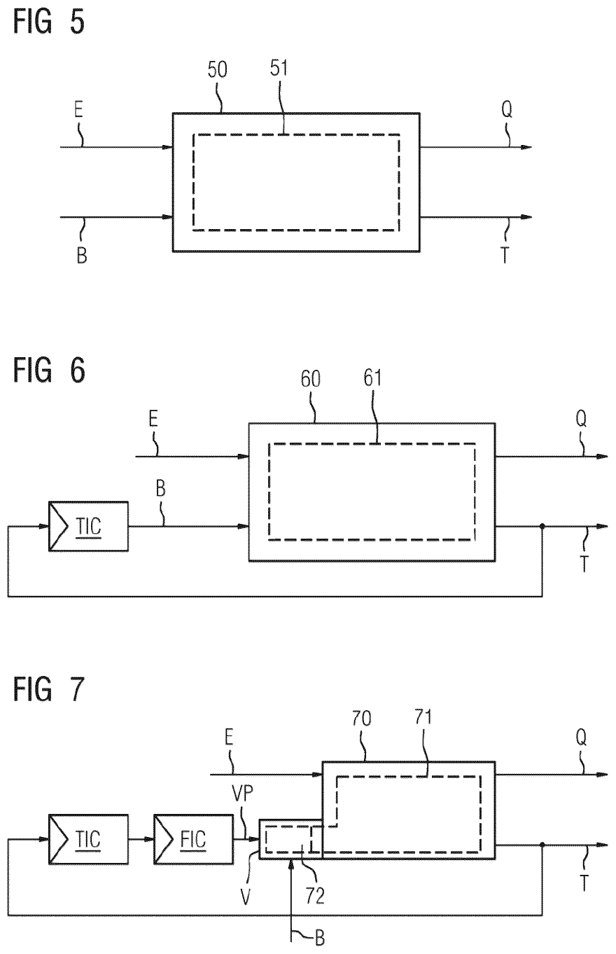

In the third step 30 c), as shown in FIG. 5, a steady-state pressure-driven simulation model 51 of the process is generated from the steady-state flow-driven simulation model 41, creating a digital process twin 51. This therefore constitutes a transition to a pressure-driven simulation that more closely reflects the physical principle of cause and effect. For example, a liquid or gaseous feedstock is drawn from a supply line at a defined pressure, and the flow rate in each component of the flow network results from the pressure difference and flow resistance. The simulation model 51 is preferably also a nonlinear model.

The simulation models 41, 51 and the digital process twins 40, 50 generated in steps 30 b) and 30 c) are used for process engineering design of the production plant, which is then physically realized in accordance with this design.

In step 30 d), piping and instrumentation planning data (for example, from a P&I diagram), particularly regarding the type and position of sensors and actuators in the production plant, is received, and in step 30 e) a dynamic pressure-driven simulation model 61 of the process is generated from the steady-state pressure-driven simulation model 51 and the pipeline and instrumentation planning data. The simulation model 61 is preferably also a nonlinear model.

A simulation tool that allows switching between steady-state and dynamic simulation, such as “gPROMS Process” by Siemens Process Systems Engineering Ltd., is advantageously used here.

For example, once dynamic simulation is selected, a parameterization dialog opens for each model component in order to specify the additional parameters that are required for dynamic simulation, such as reactor and tank volumes, heat storage capacities, and/or heat transfer coefficients. In addition, initial conditions must be specified for dynamic simulation.

As schematically illustrated in FIG. 6, a dynamic pressure-driven simulation model 61 of this kind can be used particularly advantageously in a digital process twin 60 for developing and validating control concepts, although secondary control loops are not yet taken into account. TIC here stands for a temperature controller for the operating medium B, representative of all the controllers to be validated in the plant.

In many cases, however, a controller, such as a temperature controller for the operating medium, does not access an actuator directly, but rather a secondary controller, such as a flow controller that controls the flow of the operating medium B through a valve.

In order to also take secondary control loops into account, in step 30 f) the dynamic pressure-driven simulation model 61 of the process is expanded to include actuators of secondary control loops of the plant and (as shown in FIG. 7) an initial expanded dynamic pressure-driven simulation model 71 of the process is obtained. This simulation model 71 is part of a digital process twin 70 for the extended development and validation of control concepts. The temperature controller TIC acts via a flow controller FIC on a valve V via which the flow of operating medium B can be controlled. The flow controller FIC generates a setpoint VP for the position of the valve V. The simulation model 71 is also advantageously a nonlinear model.

Slight delays only usually occur in flow control loops (valve travel time, mass inertia of the medium, low-pass filter in the sensor). As a result, simplifications and standard assumptions can often be used here. For example, it is assumed that the temperature controller TIC can control the mass flow B from the operating medium source with a standard delay. At this level of modeling, no explicit fluid mechanics model for the secondary control loop with valve and flow controller is required in the simulation model 71. Instead, a simplified model 72 for the valve V is integrated into the simulation model 71.

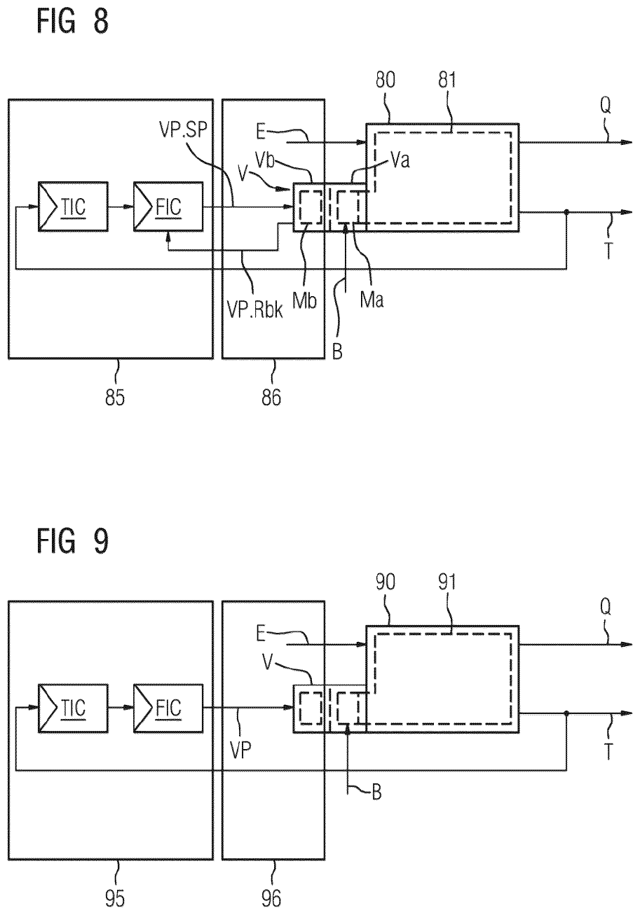

As shown in FIG. 8, the dynamic pressure-driven simulation model expanded to include secondary control loop actuators can also include explicit fluid mechanics models of the actuators. Such an extended simulation model is denoted by 81 in FIG. 8 and is part of a digital process twin 80 for virtual commissioning of the plant. The simulation model 81 is preferably also a nonlinear model.

In the case of the actuators of the secondary control loops, a distinction is made between fluid mechanics and control-related properties, here using the example of the valve V with Va (fluid mechanics) and Vb (control-related) properties. The fluid mechanics properties Va are described by a model Ma and the control-related properties are described by a model Mb.

The model Mb is part of the simulation model 81 and the model Mb is part of a digital twin 86 of the instrumentation, which will be described in more detail below.

For virtual commissioning of the plant, a process simulation tool that runs the simulation model 81 is linked to the real (original) control software of the process control system 85. The real (original) control software runs on real or virtual automation hardware.

The dynamic pressure-driven simulation model may also already be expanded to include PID controllers for the control loops (see step 30g) in the process flow of FIG. 3). However, the PID controllers are usually not needed for this use case. It is best to keep them in the model and set them to a tracking mode. The manipulated variable for the tracking operation is provided by the corresponding controller in the process control system, which thus assumes control of the process simulation.

For virtual commissioning, a more precise representation of the field level is required. The simulator should also generate feedback from actuators (for example, valve position feedback, status of motors) and, if necessary, generate a status signal for sensors. Such functionalities are highly standardizable using corresponding control-system-oriented actuator and sensor models, but often go beyond the functional scope of typical process simulation tools. It is therefore advantageous to introduce, between the process simulator (i.e., the simulation model 81) and the process control system 85, an intermediate layer that represents the field level and can be regarded as a digital instrumentation twin, denoted by reference character 86 in FIG. 8. Ideally, this intermediate layer is derived semi-automatically from the configuration of the process control system 85. Here, VP. SP is a setpoint for a valve position and VP. Rbk denotes a measured actual value for the valve position.

Virtual commissioning can be used to test the control software of the control system for errors and, in the event of an error, to correct it. Information about an error or error-free status can then be provided on an output unit (for example a display).

As evident from FIG. 9, the overall architecture from FIG. 8 can then also be used for an operator training system (OTS) after virtual commissioning. Ideally, the control system hardware is emulated on a PC (“virtual controller”) and the original graphical user interfaces of the control system's operator control and monitoring software are used. This combination of virtual control and original operator control and monitoring software of the process control system is denoted by 95 in FIG. 9. The digital process twin 90 or simulation model 91 in FIG. 9 is based on the digital process twin 80 or simulation model 81 from FIG. 8. Consequently, the simulation model 91 is linked to the operator control and monitoring software of the control system. The simulation model 91 is also advantageously a nonlinear model.

This type of operator training system gives the trainees a realistic “look and feel” of the control room in real-time. From the perspective of the plant operator, there is hardly any difference between operating the real process and its digital process twin. All the tasks that plant operators have to perform in the control room can be practiced realistically, including scenarios that rarely occur in the actual plant or involve high risks.

As shown in FIG. 10, the simulation model 61, 71 or 81 generated in step 30 e), 30 f) or 30 g) can be used in a real-time simulation, executing in parallel with operation, for a model-based soft sensor 105 of the plant. The simulation model is denoted by 101 and is part of a digital process twin 100.

The model 101 is supplied with the same values of all the input variables as those currently present in the real process or real process control system 102, such as all the inflows of feedstocks and operating media to the plant. All the measured values of the real process, represented here by the measured temperature value TIC. PV, are compared with the corresponding state variables calculated by the model 101, represented here by the temperature T. Detected deviations are typically fed into an EKF algorithm (EKF=Extended Kalman Filter) 106 in order to adjust selected uncertain model state variables or time-variant model parameters of the model 101 to the current state of the real process. This adjustment is represented by an arrow 107. The simulation model 101 is (unlike the real process) completely transparent, so that every variable that could be relevant for process control can be read online from the model 101, even if it cannot be measured directly in the real process. Here, TIC. SP denotes a setpoint for the temperature controller TIC and FIC_E.PV are actual values for the supplied feedstock flow.

A typical application involves product quality metrics or substance concentrations that are not measurable online but only sporadically determined using laboratory samples. The parameters calculated by the model 101, on the other hand, are available online and can be used in control loops instead of real sensor measurements. When results QL for parameters from laboratory samples arrive from a laboratory analysis 108, these are also used for state reconciliation in the soft sensor 105, where time delays in the laboratory analysis are taken into account by a timer DT.

The dynamic process model 101 for such a soft sensor 105 must realistically represent the behavior of the automated plant. The PID controllers are therefore preferably part of the process model, i.e., a dynamic pressure-driven simulation model is preferably used that includes the PID controllers of the control loops (see step 30g) in FIG. 3).

It is important to ensure that the closed control loops behave correctly over time in the interaction between controlled process and controller. This requires careful parameterization of both the process model components and the controllers within the model, which is performed using numerous offline simulations of the process model without an EKF solver. The model is supplied with a time series of the input variables from real historical datasets and the progression of the output variables is compared with the historical data. If necessary, the steady-state behavior is first adjusted, followed by the dynamic behavior.

Particular attention must be paid to switching between controller operating modes. If these are relevant during operation, not only the setpoint, but also the operating mode and, if necessary, then the manual value must be read from the control system into the corresponding controllers in the model. At least for this use case, the simulation model must also include a representation of the actuators (for example, valves) to enable the model to process any manual control values.

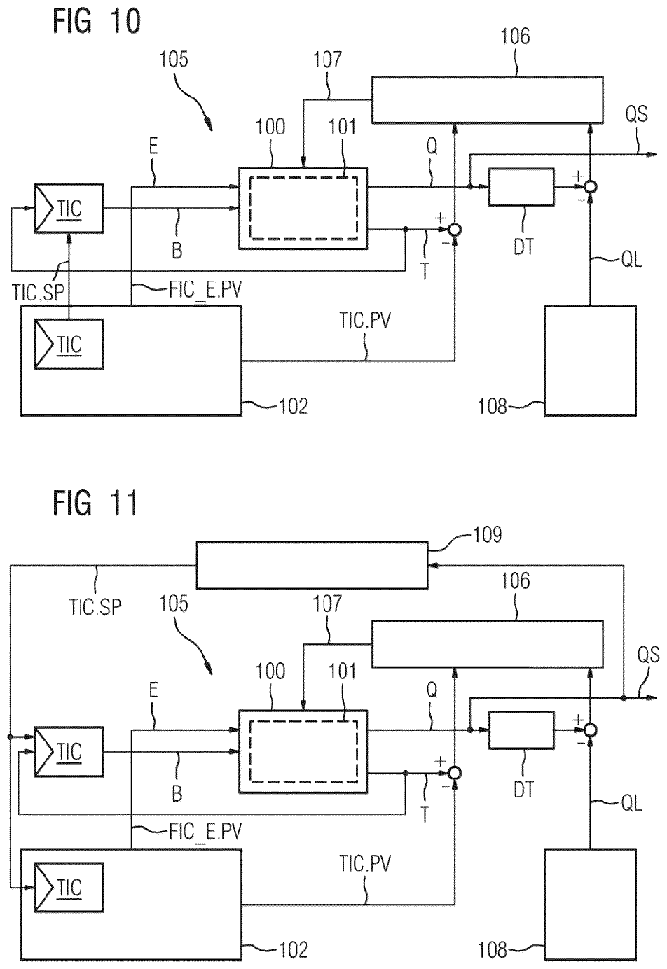

The dynamic model 101 of the automated process, including PID controllers and with parameters adjusted to match the real process state, i.e., the model 101 developed for the soft sensor 105, is exactly the right model type for nonlinear model-based predictive control (MPC). As shown in FIG. 11, the simulation model 101 is used in a real-time, concurrent simulation in combination with a nonlinear model-based predictive controller 109. The controller 109 receives as input the quality values Q calculated by the soft sensor 105 or the model 101 and uses them to compute temperature setpoint values TIC. SP which are then transferred to the process control system 102.

Some of the PID controllers of the basic automation of the process control system 102 are now operated as cascaded secondary controllers, with the controller 109 acting as the master controller. In contrast to commercially available linear predictive controllers with black box I/O models, no time-consuming step tests in the plant are required to identify a linear dynamic black box model from measurement data. The (nonlinear) dynamic model 101 can describe the behavior of the plant not only around an operating point, but also during load changes, product type changeovers, startups or shutdowns. If such requirements do not exist during production, then the rigorous dynamic model 101 can be numerically linearized and used for more cost-effective linear MPC (possibly even integrated directly into the process control system 102).

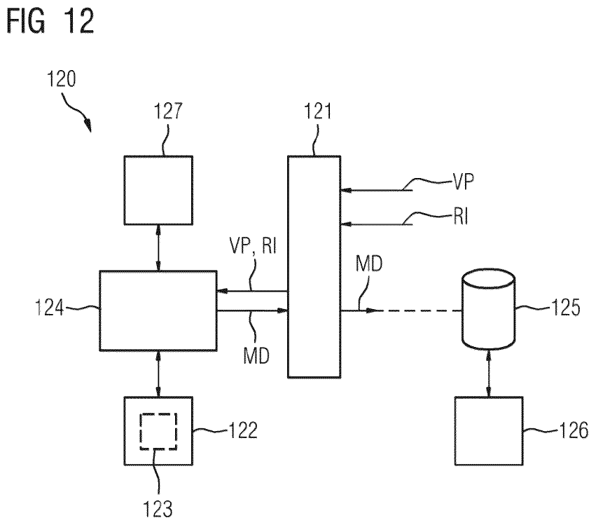

FIG. 12 schematically illustrates an inventive system 120 for generating simulation models for a digital twin of a process in a process-based production plant for a product. The system 120 comprises an interface 121 (for example, an internet connection or a USB port) that is configured to:
a) receive process flow planning data VP and piping and instrumentation planning data RI for the production plant and
b) output model data MD for each of the simulation models for storage in a data memory 125.

The system 120 comprises a first memory 122 containing commands 123 and a processor 124. The processor 124 is linked to the first memory 122 and is configured to perform steps 30a) to 30g) of the method shown in FIG. 3 when executing the commands. The memory 122 or a secondary memory 127 can be used for temporary storage of the received process flow planning data VP, piping and instrumentation data RI, and the generated model data MD.

Each of the simulation models determines product quality metrics and measurable state variables of the production plant based on the material flows of feedstocks and operating media supplied to the production plant. The model data is generated (for example, in terms of selection, content, and structure) such that the simulation models can be executed by simulation software using the model data.

The data memory 125 and the simulation software 126 can be either integrated into the system 120 or separate from it. For example, the system 120 can be hosted on an Internet-based digital platform where the generation of simulation models is offered as a service by a service provider. Here, the components 121, 122, 124 and 127 are under the control of the service provider and are located on the platform. Components 125 and 126, on the other hand, are under the control of the customer and are located either locally or on the same or a different platform. Customers then download the generated model data from the system 120 and store it in their data memory 125. From there, it can then be read by the simulation tool 126 and the simulation models can be executed.

Alternatively, the system 120, data memory 125, and simulation tool 126 can also be combined to create an integrated, for example, PC-based, overall system.

The system 120 preferably allows switching between a steady-state and a dynamic simulation as well as switching between a flow-driven and a pressure-driven simulation.

In summary, the disclosed embodiments of the invention enable the consistent use of a process master model (in this case, the steady-state flow-driven simulation model) for a digital process twin. This model is continuously developed and adapted to the respective use case without losing information from earlier phases or without having to manually re-enter it. The investment in developing a digital process twin can now be amortized across multiple use cases. This means that model-based solutions can become attractive even in fields where the time/effort required for model development with a single use case could not previously be justified. In general, this approach improves the cost-benefit ratio of model-based solutions.

Thus, while there have been shown, described and pointed out fundamental novel features of the invention as applied to a preferred embodiment thereof, it will be understood that various omissions and substitutions and changes in the form and details of the methods described and the devices illustrated, and in their operation, may be made by those skilled in the art without departing from the spirit of the invention. For example, it is expressly intended that all combinations of those elements and/or method steps that perform substantially the same function in substantially the same way to achieve the same results are within the scope of the invention. Moreover, it should be recognized that structures and/or elements and/or method steps shown and/or described in connection with any disclosed form or embodiment of the invention may be incorporated in any other disclosed or described or suggested form or embodiment as a general matter of design choice. It is the intention, therefore, to be limited only as indicated by the scope of the claims appended hereto.

1-14. (canceled)

15. A computer-implemented method for generating simulation models for a digital twin of a process of a process-based production plant for a product, the method comprising:
a) receiving process flow design data of the process of the production plant;
b) generating a steady-state flow-driven simulation model of the process from the process flow design data;
c) generating a steady-state pressure-driven simulation model of the process from the steady-state flow-driven simulation model;
d) receiving piping and instrumentation design data; and
e) generating a dynamic pressure-driven simulation model of the process from the steady-state pressure-driven simulation model and the piping and instrumentation design data, the dynamic pressure-driven simulation model including sensors and actuators of control loops of the process-based production plant;
wherein each simulation model determines measurable state variables of the production plant as a function of material flows of liquid or gaseous feedstocks and as a function of operating media supplied to the process-based production plant; and
wherein model data is generated by each simulation model and stored in a data memory such that the model data is readable from the data memory by simulation software and each simulation model is executable based on the read model data.

16. The method as claimed in claim 15, wherein each simulation model determines quality metrics for the product based on the material flows of feedstocks and operating media supplied to the production plant.

17. The method as claimed in claim 15, wherein the dynamic pressure-driven simulation model generated during step e) includes actuators of secondary control loops of the control loops or is expanded to include such actuators in a further step f).

18. The method as claimed in claim 16, wherein the dynamic pressure-driven simulation model generated during step e) includes actuators of secondary control loops of the control loops or is expanded to include such actuators in a further step f).

19. The method as claimed in claim 17, wherein the dynamic pressure-driven simulation model comprises fluid mechanics models of actuators of secondary control loops.

20. The method as claimed in claim 18, wherein the dynamic pressure-driven simulation model comprises fluid mechanics models of actuators of secondary control loops.

21. The method as claimed in claim 15, wherein the dynamic pressure-driven simulation model generated during one of step e) and f) includes proportional-integral-derivative controllers of the control loops or is expanded to include the PID controllers in a further step g).

22. The method as claimed in claim 16, wherein the dynamic pressure-driven simulation model generated during one of step e) and f) includes proportional-integral-derivative controllers of the control loops or is expanded to include the PID controllers in a further step g).

23. The method as claimed in claim 17, wherein the dynamic pressure-driven simulation model generated during one of step e) and f) includes proportional-integral-derivative controllers of the control loops or is expanded to include the PID controllers in a further step g).

24. The method as claimed in claim 15, wherein the simulation model generated during one of step b) and c) is utilized for process engineering design of the production plant, and the process-based production plant is physically realized based on this design.

25. The method as claimed in claim 16, wherein the simulation model generated during one of step b) and c) is utilized for process engineering design of the production plant, and the process-based production plant is physically realized based on this design.

26. The method as claimed in claim 15, wherein the simulation model generated during one of step e), f) and g) is utilized to develop and validate control concepts, and the control of the process-based production plant is physically realized based on this design.

27. The method as claimed in claim 15, wherein the simulation model generated during one of step e), f) and g) is utilized to virtually commission the process-based production plant, the simulation model being linked to control software of the process-based production plant to test said process-based production plant to ensure error-free operation during said virtual commissioning of the process-based production plant.

28. The method as claimed in claim 15, wherein the simulation model generated during one of step e), f) and g) is utilized to train plant operating personnel, the simulation model being linked to an operator control and monitoring software of the process-based production plant during said training of the plant operating personnel.

29. The method as claimed in claim 15, wherein the simulation model generated during one of step e), f) and g) is utilized for a model-based soft sensor of the process-based production plant.

30. The method as claimed in claim 15, wherein the simulation model generated during one of step e), f) and g) is utilized for model-based predictive control of the process-based production plant.

31. The method as claimed in claim 15, wherein the simulation model generated during one of step e), f) and g) is utilized for an assistance system for an operator of the process-based production plant, the simulation model being linked to control software of the process-based production plant when being utilized for the assistance system for the operator.

32. A system for generating simulation models for a digital twin of a process in a process-based production plant for a product, the system comprising:
an interface configured to:
a) receive process flow planning data and piping and instrumentation planning data of the process-based production plant; and
b) output model data of each simulation model for storage in a data memory;
a memory containing commands;
a processor linked to the memory, the processor, when executing the commands being configured to:
a) receive the process flow design data of the process of the production plant via the interface;
b) generate a steady-state flow-driven simulation model of the process from the process flow design data;
c) generate a steady-state pressure-driven simulation model of the process from the steady-state flow-driven simulation model;
d) receive piping and instrumentation design data; and
e) generate a dynamic pressure-driven simulation model of the process from the steady-state pressure-driven simulation model and the piping and instrumentation design data, the dynamic pressure-driven simulation model including sensors and actuators of control loops of the process-based production plant;
wherein each simulation model determines measurable state variables and quality metrics for the product of the process-based production plant based on material flows of liquid or gaseous feedstocks and operating media supplied to the process-based production plant; and
wherein the model data is generated such that each simulation model is executable by simulation software based on the model data.

33. A computer program comprising commands which, when executed by a processor of computer, cause the computer to implement the method as claimed in claim 15.

34. A non-transitory computer-readable storage medium encoded with commands which, when executed by a processor of a computer, cause the computer to generate simulation models for a digital twin of a process in a process-based production plant for a product, the commands comprising:
a) program code for receiving process flow design data of the process of the production plant;
b) program code for generating a steady-state flow-driven simulation model of the process from the process flow design data;
c) program code for generating a steady-state pressure-driven simulation model of the process from the steady-state flow-driven simulation model;
d) program code for receiving piping and instrumentation design data; and
e) program code for generating a dynamic pressure-driven simulation model of the process from the steady-state pressure-driven simulation model and the piping and instrumentation design data, the dynamic pressure-driven simulation model including sensors and actuators of control loops of the process-based production plant;
wherein each simulation model determines measurable state variables of the production plant as a function of material flows of liquid or gaseous feedstocks and as a function of operating media supplied to the process-based production plant; and
wherein model data is generated by each simulation model and stored in a data memory such that the model data is readable from the data memory by simulation software and each simulation model is executable based on the read model data.
